(19) United States
(12) Patent Application Publication
(10) Pub. No.: US 2024/0204766 A1
(43) Pub. Date: Jun. 20, 2024

(54) INTELLIGENT SEMICONDUCTOR SWITCH WITH QUASI-DIGITAL CURRENT LIMITATION

(71) Applicant: Infineon Technologies AG, Neubiberg (DE)

(72) Inventors: Christian Djelassi-Tscheck, Villach (AT); Alexander Mayer, Treffen (AT); Mario Tripolt, Ferndorf (AT); Vincent Thiery, Aix En Provence (FR); Markus Huebl, Villach (AT); Bernhard Auer, Millstatt (AT)

(21) Appl. No.: 18/528,469

(22) Filed: Dec. 4, 2023

(30) Foreign Application Priority Data
Dec. 16, 2022 (DE) 102022133711.1

(51) Int. Cl. H03K 17/082; H03K 17/687

(52) U.S. Cl. CPC H03K 17/0822; H03K 17/687; H03K 2217/0027; H03K 2217/0036

(57) ABSTRACT

A current limitation concept for an intelligent semiconductor switch is described herein. In accordance with one embodiment, a method performed by the intelligent semiconductor switch comprises generating a gate current and switching on a power transistor by applying the gate current to the gate electrode of the power transistor. The method further comprises determining information regarding a load current passing through the power transistor and controlling—based on the information regarding the load current—the load current by reducing the gate current applied to the gate electrode of the power transistor. When the load current exceeds a first threshold value, the gate current is reduced by a specific amount, and when the load current exceeds a third threshold value, the gate current is further reduced by sinking a discharge current, which has a third current level, from the gate electrode of the power transistor.

### TECHNICAL FIELD

The present disclosure relates to the field of intelligent semiconductor switches and in particular to an intelligent semiconductor switch including a current limitation function.

### BACKGROUND

So-called intelligent semiconductor switches are integrated circuits which include, besides the semiconductor switch as such, additional circuits that are configured to perform various auxiliary functions such as current measurement, temperature measurement, current limitation, circuit diagnosis, digital communication with other circuits, etc. Some of these auxiliary functions are implemented to protect the integrated circuit from being operated outside its safe operation area (SOA). Overcurrent switch-off and current limitation are examples of such protective functions and are a requirement for many applications.

Dependent on the electric load to be switched (e.g. light bulbs, capacitive or inductive loads different) and on the cause of an overcurrent (e.g. short circuit or high inrush currents, short transient pulses) a specific type of over-current protections (current limitation or temporary over-current switch-off) may be more suitable than others. The inventors have set themselves the object to improve existing concepts of overcurrent protection in intelligent semiconductor switches.

### SUMMARY

The above-mentioned object is achieved by the circuits of claims 1 and 11 and the method of claims 14. Various embodiments and further developments are covered by the dependent claims. In accordance with one embodiment an integrated circuit comprises a power transistor connected between a supply terminal and an output terminal, a control circuit coupled to a gate electrode of the power transistor and configured to apply a gate current to the gate electrode to turn the power transistor on or off, and a current sensing circuit configured to provide information regarding a load current passing through the power transistor. The integrated circuit further comprises a current control circuit coupled to the gate electrode and configured to generate a discharge current for discharging the gate based on the information regarding the load current, wherein the level of the discharge current corresponds to a first current level, when the load current exceeds a first threshold value, and wherein the level of the discharge current corresponds to a third current level, when the load current exceeds a third threshold value.

In accordance with another embodiment an integrated circuit comprises a power transistor connected between a supply terminal and an output terminal, a control circuit coupled to a gate electrode of the power transistor and configured to apply a gate current to the gate electrode to turn the power transistor on or off, and a current sensing circuit configured to provide information regarding a load current passing through the power transistor. The integrated circuit further comprises a current control circuit coupled to the gate electrode and configured to generate a discharge current for discharging the gate based on the information regarding the load current and to cause the control circuit to reduce the gate current while the power transistor is switched on, wherein the gate current output by the control circuit is reduced, when the load current exceeds a first threshold value, and wherein the level of the discharge current is set to a third current level, when the load current exceeds a third threshold value.

A further embodiment relates to a method that may be performed by an intelligent semiconductor switch. Accordingly, the method comprises generating a gate current and switching on a power transistor by applying the gate current to the gate electrode of the power transistor. The method further comprises determining information regarding a load current passing through the power transistor and controlling—based on the information regarding the load current—the load current by reducing the gate current applied to the gate electrode of the power transistor. When the load current exceeds a first threshold value, the gate current is reduced by a specific amount, and when the load current exceeds a third threshold value, the gate current is further reduced by sinking a discharge current, which has a third current level, from the gate electrode of the power transistor.

### BRIEF DESCRIPTION OF THE DRAWINGS

The embodiments described herein can be better understood with reference to the following drawings and descriptions. The components in the figures are not necessarily to scale; instead emphasis is placed upon illustrating the principles of the embodiments shown in the figures. Moreover, in the figures, like reference numerals designate corresponding parts. In the drawings:

FIG. 1 illustrates one example of an intelligent semiconductor switch with a current limitation function.

FIG. 2 illustrates a modification of the example of FIG. 1 in accordance with one embodiment.

FIG. 3 includes a set of timing diagrams illustrating the function of the example of FIG. 2 in different scenarios.

FIG. 4 illustrates one exemplary implementation of the circuit of FIG. 2 in more detail.

FIGS. 5 and 6 illustrate two exemplary modifications of the circuit of FIG. 4.

FIG. 7 is a flow chart illustrating one embodiment of a method which may be performed by the circuits.

### DETAILED DESCRIPTION

Before various embodiments are described in more detail, an example of a conventional intelligent semiconductor switch (smart switch) is described with reference to FIG. 1. The example described herein relate high-side switches, which are connected between a supply voltage terminal and an electric load. However, it is understood that the concepts described herein are readily applicable to low-side switches.

In the example of FIG. 1, the intelligent semiconductor switch 10 has (inter alia) a supply terminal VS and an output terminal OUT. A power transistor T_{L} (i.e. its load current path to be precise) can connect and disconnect the supply terminal VS and the output terminal OUT dependent on the control voltage received at its control electrode. In the present example, the power transistor T_{L} is an n-channel MOS field-effect transistor (MOSFET) whose drain electrode is connected to the supply terminal VS and whose source electrode is connected to the output terminal OUT. In case of a MOSFET the mentioned control voltage is supplied to the gate electrode of the transistor and thus referred to as gate voltage V_{G}. In the present example, the supply voltage supplied to the supply terminal VS is denoted as V_{S} and the electric load is symbolized by an impedance Z_{L} that is connected between the output terminal OUT and a reference (e.g. ground) potential. The voltage across the electric load is denoted as V_{OUT} (which is equal to the source voltage).

As almost any intelligent semiconductor switch, the example of FIG. 1 includes a current sense circuit 13. The current sensing is usually accomplished using a so-called Sense-FET (sense transistor T_{S}), i.e. a transistor that is operated in approximately the same operating point as the power transistor T_{L} and therefore carries a drain-source current is which is indicative of (approximately proportional to) the load current in passing through the power transistor T_{L}. In the present example, the drain and gate electrodes of the sense transistor T_{S} are connected to the drain and, respectively, source electrodes of the power transistor T_{L}. Further, the source electrode of the sense transistor T_{S} is connected to the output terminal (and thus to the source electrode of the power transistor T_{L}) via a current sense resistor R_{S}. The resistance of the sense resistor R_{S} may be quite small and its purpose is basically to convert the drain-source current is passing though the sense transistor T_{S} into a respective voltage signal V_{CS} (current sense signal). In an idealized view, the current sense signal V_{CS} is proportional to the load current in passing through the power transistor T_{L} (V_{CS}˜i_{L}). In one example, the power transistor is composed of a plurality of transistor cells arranged in a so-called cell array, and the sense transistor is composed of a only a couple of transistor cells in the same cell array. The ratio of the transistor cells of the two transistors determines the factor of proportionality between the load current i_{L} and the sense current is (e.g. i_{S}/i_{L}=10⁵=100 μA/A).

The example of FIG. 1 further includes a current limitation circuit 14, which can limit the load current i_{L} so that it does not exceed a specified current limit i_{LIM}. In the present example, the current limit i_{LIM} is determined by the (e.g. constant) reference voltage V_{REF} that is used by the current limitation circuit 14. The reference voltage V_{REF} is generated with respect to the electric potential of the output terminal OUT and thus is in the same voltage domain like the current sense signal V_{CS}. A situation V_{CS}=V_{REF} indicates (in an idealized view) that the load current i_{L} equals the current limit i_{LIM} (i_{L}=i_{LIM}).

The current sense circuit 14 of FIG. 1 includes a difference amplifier OA (e.g. an operational amplifier) which receives, as input voltages, the current sense signal V_{CS} and the reference voltage V_{REF}. The amplifier amplifies the difference V_{CS}−V_{REF} with a relatively high gain. The output of the amplifier OA is coupled to the control terminal (gate terminal in case of a MOS transistor) of a transistor T₁ (output stage of current limitation circuit 14) that is coupled between the gate electrode and the source electrode of the power transistor T_{L}. That is, when driven into a conductive state, the transistor T₁ provides a current path (current i_{REG}) between the gate and the source of the power transistor T_{L} for discharging its gate (thus reducing the load current). Accordingly, as long as the difference V_{CS}−V_{REF} at the input of the amplifier OA is negative (i.e. V_{CS}<V_{REF} and i_{L}<i_{LIM}) the amplifier OA outputs a negative voltage and the transistor T₁ is off (not conductive). As soon as the difference V_{CS}−V_{REF} at the input of the amplifier OA becomes zero (i.e. V_{CS}=V_{REF} and i_{L}=i_{LIM}) any further increase of the load current it will cause the difference V_{CS}−V_{REF} to become positive. As a result, the amplifier will output a positive gate voltage to the transistor T₁, the transistor T₁ will become conductive and discharge the gate of the power transistor T_{L}, by sinking the current i_{REG} which, in turn, will cause a reduction of the load current i_{L} (and the sense current i_{S}). One can see that the transistor T₁, the power transistor T_{L}, the sense transistor T_{S} and the sense resistor R_{S} result in a negative feedback to the input of the amplifier OA, which leads to a stable state of the feedback loop and an effective current limitation to the current limit i_{LIM} if the gain of the amplifier is sufficiently high.

In the above explanations concerning the current limitation, it is assumed that the power transistor T_{L} is actively driven into an on-state. In the example of FIG. 1 a control circuit 12 generates a gate current i_{G0} which is supplied to the gate of the power transistor T_{L} (and also the gate of the sense transistor T_{S}) and charges the electrodes (i.e. gate-source capacitance). While charging the gate electrodes, the gate voltage V_{G} rises until a maximum gate voltage is reached. A positive gate current i_{G0} is only generated when a logic signal V_{IN} received by the control circuit 12 indicates (e.g. by a High level) a switch-on of the power transistor T_{L}. Similarly, a negative gate current may be generated when the logic signal V_{IN} indicates (e.g. by a Low level) a switch-off of the power transistor T_{L}. Suitable control circuits are as such known and thus not explained here in more detail. Usually, the control circuit includes switchable current sources that selectively provide the positive and the negative gate current i_{G0} dependent on the logic level of the logic signal V_{IN}. The (positive or negative) gate current may be substantially constant until the current sources in the control circuit output stage saturate as the resulting gate voltage V_{G} approaches the (upper or lower) supply voltage rail of the control circuit 12. As the current example is a High-side switch, a level shifter 11 is used to transfer the input signal received at the input terminal IN into the floating supply voltage domain of the control circuit 12. The supply voltage V_{CP} of the control circuit 12 may be generated by a charge pump circuit (not shown in FIG. 1), which is as such commonly known and thus not discussed herein in more detail.

In practice the electric load it is not a single component. The wires connecting the output terminal OUT and an electric load may have a considerable impedance (e.g. in the range of a few μH). Furthermore, a (buffer) capacitor of several hundred μF may be connected in parallel of the electric load, which may give rise to significant inrush currents when switching the on the power transistor T_{L}. Cold light bulbs also cause high inrush currents. These inrush currents may be significant (e.g. up to 80 Amperes or more) and, as a consequence, the temperature of the active area of the power transistor T_{L}, may increase very quickly. Even more critical than the absolute temperature is the temperature gradient across the semiconductor chip, which is usually measured as a temperature difference T_{J}−T_{A} between the junction temperature T_{J} in the active area of the power transistor T_{L}. (e.g. measured in the cell array) and the “ambient” temperature T_{A} which may be measured on the same chip but remotely from the active area of the power transistor.

Some intelligent semiconductor switches have an over-temperature protection which temporarily switches the power transistor T_{L}, off upon detection of an excess temperature (e.g. the mentioned difference T_{J}−T_{A} exceeding a specified threshold), and switches the power transistor T_{L}, on again once the temperature difference has dropped by a certain amount. Some intelligent semiconductor switches use an over-current switch-off instead of a pure current limitation. That is, the power transistor T_{L} is temporarily switched off upon detection of an over-current (i.e. when the load current exceeds a specified switch-off threshold), and is again switched on a short time period later. Over-current protection and over-temperature protection may be combined in some embodiments.

The current limit used for current limitation or the over-current switch-off threshold as well as the temperature threshold used for over-temperature protection may be specified and optimized for a specific application. Usually, the circuit designer selects these parameters to ensure that the temperature (or temperature difference) of the power transistor, the temperature of the cables and/or the temperatures of other components connected to the intelligent semiconductor switch (e.g. a buffer capacitor of the load) remain within a safe range. Furthermore, non-linear effects like limit-cycles (e.g. toggling) and other instabilities have to be avoided. The embodiments discussed below aim at improving existing concepts.

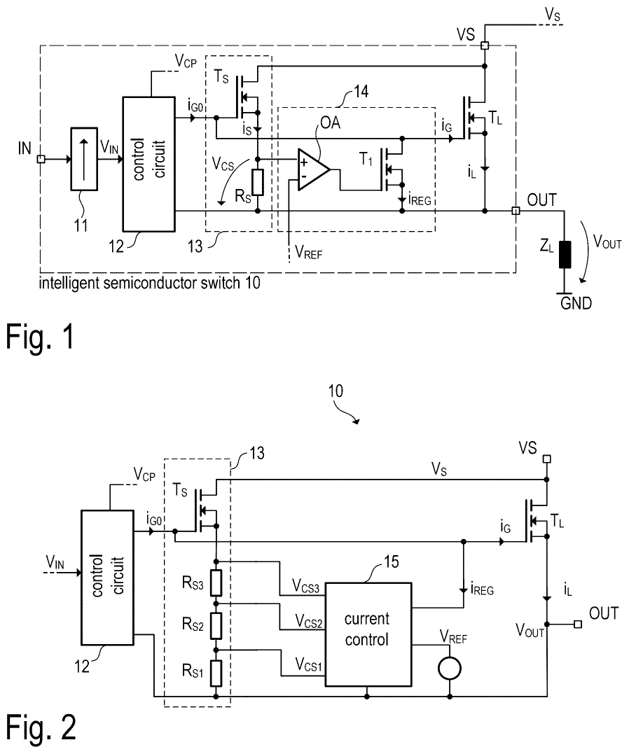

Various embodiments are now described with reference to FIG. 2, which can be regarded as a modification/improvement of the example of FIG. 1. The power transistor T_{L} and the sense transistor T_{S} are connected in the same way as in the example of FIG. 1. Also the control circuit 12 may be connected in the same way as in the example of FIG. 1 and generated, based on the (level-shifted) input signal V_{IN}, a positive and negative gate current i_{G0} to charge and, respectively, discharge the gate electrode of the power transistor T_{L} in order to switch it on and off.

Different from the previous example, the current sense circuit includes a chain of three sense resistors R_{S1}, R_{S2}, and R_{S3} (instead of a single sense resistor R_{S} as in FIG. 1) which allows to provide three respective current sense signals V_{CS1}, V_{CS2}, and V_{CS3}. The voltage V_{CS1} is the voltage drop across resistor R_{S1} (V_{CS1}=i_{S}·R_{S1}), the voltage V_{CS2} is the voltage drop across the series connection of resistors R_{S1} and R_{S2} (V_{CS2}=i_{S}·(R_{S1}+R_{S2})), and the voltage V_{CS3} is the voltage drop across the series connection of resistors R_{S1} R_{S2}, and R_{S3} (V_{CS3}=i_{S}·(R_{S1}+R_{S2}+R_{S3})). Other embodiments may use more or less current sense resistors connected in series. The intelligent semiconductor switch 10 of FIG. 2 includes a current control circuit 15 instead of the current limiting circuit 14 of FIG. 1). The current control circuit 15 receives a reference voltage V_{REF} as well as the current sense signals V_{CS1}, V_{CS2}, and V_{CS3}, and provides—based on these current sense signals and the reference voltage—a current i_{REG} at its output, which is coupled to the gate electrode of the power transistor T_{L}. A positive current i_{REG} drains charge from the gate electrode of the power transistor T_{L} (thereby reducing the gate voltage V_{G}) to reduce the load current i_{L}. The level shifter 11, the load and other components of the intelligent semiconductor switch have been omitted in FIG. 2 to keep the illustration simple. The function of the current control circuit 15 is discussed in more detail further below.

It is noted that using multiple sense resistors R_{S1}, R_{S2}, R_{S3} to generate multiple current sense signals V_{CS1}, V_{CS2}, and V_{CS3} is merely a way to implement multiple current thresholds i_{LIM1}, i_{LIM2}, i_{OC} with only a single reference voltage V_{REF}. Accordingly, the situation V_{CS3}=V_{REF} corresponds to the load current reaching the first threshold (i_{L}=i_{LIM1}), the situation V_{CS2}=V_{REF} corresponds to the load current reaching the second threshold (i_{L}=i_{LIM2}), and the situation V_{CS1}=V_{REF} corresponds to the load current reaching the third threshold (i_{L}=i_{OC}). The same result can be achieved by using a single current sense signal V_{CS} and a single sense resistor R_{S} (like in FIG. 1), when multiple reference voltages (e.g. V_{REF1}, V_{REF2}, and V_{REF3}) are used. Accordingly, other embodiments may have only one sense resistor but multiple reference voltage sources. Some embodiments may use only two thresholds, and some may use more than three thresholds/current limits.

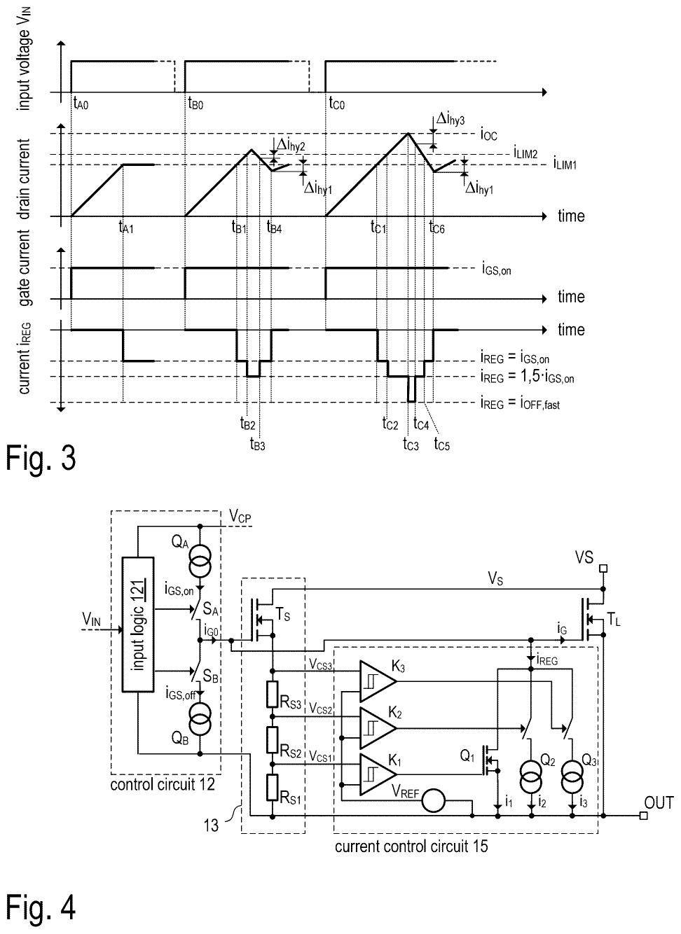

The function/behavior of the current control circuit 15 is now discussed using an exemplary scenario illustrated by the timing diagrams of FIG. 3. FIG. 3 illustrates three different scenarios, in which the load current i_{L}. (drain current of power transistor T_{L}) starts to rise after the switch-on of the power transistor T_{L} is triggered by a level transition in the input signal V_{IN} from a Low level to a High Level at times t_{A0}, t_{B0}, and t_{C0} (see FIG. 3, first diagram). At this point it is noted that the steepness of the slope of the load current i_{L}. (sec FIG. 3, second diagram) after a switch-on depends (inter alia) on the electric load connected to the intelligent semiconductor switch, and the target level of the load current after the switch-on phase also depends on the electric load unless the current control circuit 14 intervenes (which is the case in the depicted scenarios). Accordingly, the depicted drain current waveforms are arbitrary examples chosen to illustrate the function of the circuit of FIG. 3. As explained above, three current thresholds are used, i.e. i_{LIM1}, i_{LIM2}, and i_{OC}.

The third timing diagram of FIG. 3 illustrates the output of the control circuit 12, i.e. the gate current i_{G}=i_{GS,on}. As a consequence, beginning at times t_{A0}, t_{B0}, and t_{C0}, the gate electrode of the transistor T_{L} is charged, the transistor T_{L} becomes conductive, and the load current i_{L}, which is output to the load at the output terminal OUT, starts to rise. The fourth diagram of FIG. 3 illustrates the current i_{REG} (discharge current) which the current control circuit 15 sinks from the gate electrode of transistor T_{L} when the load current in hits certain thresholds.

In the first scenario (starting at time t_{A0}) the discharge current i_{REG} is zero until the load current i_{L} reaches the first threshold i_{LIM1} at time t_{A1}. As soon as the load current i_{L} of the power transistor T_{L} reaches the threshold value i_{LIM1}, the current control circuit 15 sets the level of the discharge current i_{REG} to a first current level. In one example, this fist current level is the negative output current of the control circuit 12, i.e. i_{REG}=i_{GS,on}. The output current i_{G0}=i_{GS,on} of the control circuit 12 and the discharge current i_{REG} superpose, so that the effective gate current i_{G} equals to difference i_{GS,on}−i_{REG}. In the mentioned example (i_{REG}=i_{GS,on} if i_{L}≥i_{LIM1}) the effective gate current i_{G} is zero, and the charge stored in the gate-source capacitance slowly decreases due to leakage only. The discharge current i_{REG} may be reset to zero when the load current i_{L} drops below the threshold i_{LIM1}. In some embodiments, the current control circuit 15 implements a hysteresis and the discharge current i_{REG} is reset to zero when the load current i_{L} drops below the somewhat lower threshold I_{LIM1}−Δi_{hy1} (Δi_{hy1} denotes the width of the hysteresis). In the first scenario, setting the effective gate current i_{G} to zero is enough to prevent the load current i_{L} from rising beyond the threshold i_{LIM1}.

In the second scenario (starting at time t_{B0}) the discharge current i_{REG} is again zero until the load current i_{L} reaches the first threshold i_{LIM1} at time t_{B1}. Like in the first scenario the discharge current i_{REG} is set to the first current level which may be i_{GS,on} so that the effective gate current i_{G} becomes zero as explained above. However, in the second scenario the load current i_{L}, nevertheless, rises beyond the threshold i_{LIM1} and reaches the second threshold i_{LIM2} at time t_{B2}. When the load current it reaches the second threshold i_{LIM2} at time t_{B2} then the level of the discharge current i_{REG} is set to a second current level. In the depicted embodiment the second current level equals 1.5·i_{GS,on}. Accordingly, the superposition i_{GS,on}−i_{REG} (i.e. the effective gate current) becomes −0.5·i_{GS,on} and the gate of the power transistor is actively discharged with a relatively small current.

The reduction of the effective gate current is sufficient to achieve a reduction of the load current iL. When the load current i_{L} falls below the second threshold i_{LIM2} (or i_{LIM2}−Δi_{hy2} if a hysteresis is used), the discharge current i_{REG} is set again to the first current value, e.g. i_{REG}=i_{GS,on} (see FIG. 3, time t_{B3}). When the load current in falls below the first threshold i_{LIM1} (or i_{LIM1}−Δi_{hy1} if a hysteresis is used), the discharge current i_{REG} is set again to zero (see FIG. 3, time t_{B4}).

In the third scenario (starting at time t_{C0}) the discharge current i_{REG} is again zero until the load current it reaches the first threshold i_{LIM1} at time t_{C1}. Like in the second scenario, the discharge current i_{REG} is set to the first current level, which may be i_{GS,on} so that the effective gate current i_{G} becomes zero as explained above. Subsequently, like in the second scenario the load current i_{L} rises beyond the threshold i_{LIM1} and reaches the second threshold i_{LIM2} at time t_{C2}. At this time the level of the discharge current i_{REG} is set to a second current level, which equals 1.5·i_{GS,on} in the present example. However, in the present example, the load current still rises further until it reaches the third threshold i_{OC} at time t_{C3}. In response to the load current i_{L} reaching the third threshold i_{OC}, the discharge current is set to a third current level denoted as i_{OFF,fast}, which is significantly higher than the “normal” gate current i_{GS,on}. The superposition i_{G}=i_{GS,on}−i_{REG} now equals i_{GS,on}−i_{OFF,fast}, which is a negative current high enough (in magnitude) to discharge the gate very quickly, thereby forcing the load current to drop (after a small overshot) below the third threshold i_{OC} (or i_{OC}−Δi_{hy3} if a hysteresis is used), which happens at time t_{C4} in the depicted example. At times t_{C5} and t_{C6} the current level of the discharge current is reset to the second current level (e.g. i_{REG}=i_{GS,on}) and, respectively, the first current level (i_{REG}=0) as the load current further drops below the second threshold i_{LIM2} and the first threshold i_{LIM1}, respectively.

As can be seen from the scenarios described above and depicted in FIG. 3, the current control circuit 15 is can change the discharge current i_{REG} (and thus the effective gate current i_{GS,on}=i_{REG}) quasi-digitally by discrete steps as soon as the load current reaches certain thresholds. These thresholds i_{LIM1}, i_{LIM2}, and i_{OC} may be configurable and thus may be adapted to a specific application.

FIG. 4 illustrates a more detailed example similar to the circuit of FIG. 2. The power transistor T_{L} and the current sense circuit 13 with the sense transistor T_{S} are the same as in the previous example. The control circuit 12 includes an output stage composed of two current sources Q_{A} and Q_{B} that can be connected to the output node, which is coupled to the gate of the power transistor T_{L}, via electronic switches S_{A} and S_{B}, respectively. The current source Q_{A} outputs the current i_{GS,on} which is output by the control circuit 12 when switch S_{A} is closed (and switch S_{B} is open) in order to charge the gate of power transistor T_{L}. Similarly, the current source Q_{B} outputs the current −i_{GS,off} which is sunk by the control circuit 12 when switch S_{B} is closed (and switch S_{A} is open) in order to discharge the gate of the power transistor T_{L}. The control circuit 12 further includes the input logic 121 which is configured to generate the control signals for the electronic switches S_{A} and S_{B} in accordance with the (e.g. level shifted) input signal V_{IN}. For example, if the input signal V_{IN} has a High level (logical 1), then the input logic 121 may activate the switch S_{A} and deactivate the switch S_{B} to output the current i_{GS,on}. Conversely, if the input signal V_{IN} has a Low level (logical 0), then the input logic 212 may activate the switch S_{B} and deactivate the switch S_{A} to output the current i_{GS,off} at the output of the control circuit 12.

As can be seen from FIG. 4, the current source Q_{A} is connected in series with the switch S_{A} and arranged between an output node and a supply node at which the supply voltage V_{CP} is provided. The current source Q_{B} is connected in series with the switch S_{B} and arranged between an output node and a reference node at which the voltage V_{OUT} is provided (floating reference voltage). The current sources Q_{A} and Q_{B} may be implemented in any conventional manner. For example, the current sources Q_{A} and Q_{B} may be implemented using current mirrors wherein the currents i_{GS,on} and i_{GS,off} are derived from a single reference current, that may be provided by a constant current circuit.

The current control circuit 15 of FIG. 4 receives the three current sense signals V_{CS3}, V_{CS2}, and V_{CS1} from the current sense circuit 13, which has already been discussed above with reference to FIG. 2. The three current sense signals V_{CS3}, V_{CS2}, and V_{CS1} are supplied to a first input of comparators K₃, K₂, and K₁, respectively. The second inputs of these comparators receive the reference voltage V_{REF}. That is, comparator K₃ signals, at its output, whether the condition V_{CS3}>V_{REF} is fulfilled (equivalent to i_{L}>i_{LIM1}), comparator K₂ signals, at its output, whether the condition V_{CS2}>V_{REF} (equivalent to i_{L}>i_{LIM2}) is fulfilled, and comparator K₁ signals, at its output, whether the condition V_{CS1}>V_{REF} (equivalent to i_{L}>i_{OC}) is fulfilled.

The current control circuit 15 includes a transistor Q₁ and current sources Q₂ and Q₃ which can be activated by the output signals of the comparators K₁, K₂, and K₃, respectively. The current sources Q₂ and Q₃ are activated and deactivated by switching the corresponding electronic switch S₁ and S₂ (connected in series to the respective current source) on and off, respectively. The current transistor Q₁ and the current sources Q₂ and Q₃ are connected in parallel so that the currents i₁, i₂, i₃ superpose at the output node at which the discharge current i_{REG} is sunk from the gate of the power transistor T_{L}. That is, the discharge current i_{REG} is equal to the sum of the currents i₁, i₂, and i₃ passing through the transistor Q₁, the current source Q₂, and the current source Q₃, respectively. In the present example, again four different scenarios can be distinguished.

First scenario: i_{L}<i_{LIM1}<i_{LIM2}<i_{OC}. If this condition is true, then all three sense voltages V_{CS3}, V_{CS2}, and V_{CS1} are lower than the reference voltage V_{REF} and the discharge current i_{REG} is zero. The effective gate current i_{G}=i_{GS,on}−i_{REG} equals to i_{GS,on} and the power transistor is fully switched on (lowest on-resistance R_{ON}).

Second scenario: i_{L}≥i_{LIM1}. If this condition is true, then the current sense voltage V_{CS3} reaches or exceeds the reference voltage V_{REF} (V_{CS3}≥V_{REF}, V_{CS2}<V_{REF}, V_{CS1}<V_{RE}F). As a consequence, the comparator K₃ activates the current source Q₃ while current source Q₂ and transistor Q₁ are still inactive. Accordingly, i_{REG} equals i₃, wherein i_{REG}=i₃=i_{GS,on} in the present example. Thus, the discharge current i_{REG} exactly compensates for the current i_{GS,on} output by the control circuit 12 and the effective gate current i_{G}=i_{GS,on}−i_{REG} equals to zero amperes.

Third scenario: i_{L}≥i_{LIM2}. If this condition is true, then the current sense voltage V_{CS2} reaches or exceeds the reference voltage V_{REF} (V_{CS3}≥V_{REF}, V_{CS2}≥V_{REF}, V_{CS1}<V_{REF}). As a consequence, the comparator K₂ activates the current source Q₂ while current source Q₃ is also active but transistor Q₁ is still inactive. Accordingly, i_{REG} equals i₂+i₃, wherein i_{REG}=i₂+i₃=1.5·i_{GS,on} in the present example (i.e. i₂=0.5·i_{GS,on}). Thus, the discharge current i_{REG} overcompensates for the current i_{GS,on} output by the control circuit 12 and the effective gate current i_{G}=i_{GS,on}−i_{REG}=0.5·i_{GS,on} is negative and the gate of the power transistor TL is actively discharged.

Fourth scenario: i_{L}≥i_{OC}. If this condition is true, then the current sense voltage V_{CS1} reaches or exceeds the reference voltage V_{REF} (V_{CS3}≥V_{REF}, V_{CS2}≥V_{REF}, V_{CS1}≥V_{REF}). As a consequence, the comparator K₁ activates the transistor Q₁ while current sources Q₂ and Q₃ are also active. Accordingly, i_{REG} equals i₁+i₂+i₃=i_{OFF,fast}. As the transistor Q₁—when activated—provides a comparably low-ohmic current path between gate and source of the power transistor T_{L} the resulting discharge current i_{REG}=i_{OFF,fast} will quickly discharge the gate capacitance of the power transistor T_{L}. As a consequence, the resistance of the drain-source path of the power transistor T_{L} will increase quickly to reduce the load current i_{L}.

The current sources Q₂ and Q₃ may be implemented in any common manner. For example, current mirrors may be used to derive the currents i₂ and i₃ from a reference current. This reference current may be same that is used by the control circuit 12 to generate the currents i_{GS,on} and i_{GS,off}. At this point it should be emphasized that the circuit of FIG. 4 has to be regarded as an example for a circuit that behaves as it has been discussed above with reference to FIG. 2. It is clear from FIG. 4 that the same function can be implemented with only one current sense signal but three different reference voltages. Moreover, in some embodiments only two thresholds/current sense signals may be used, whereas in other embodiments four or more thresholds/current sense signals may be used.

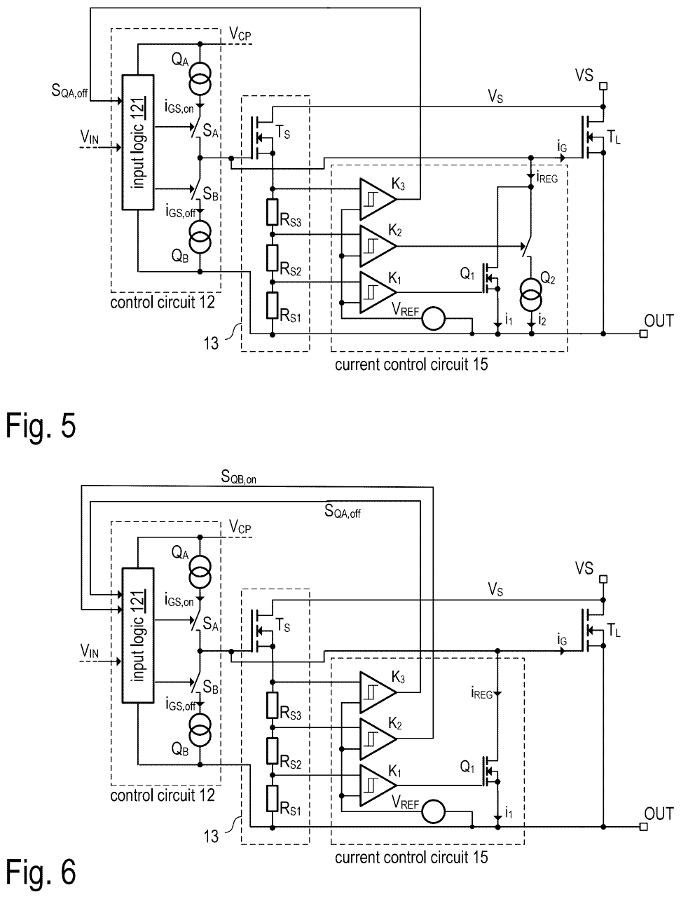

In the above-mentioned second scenario (i_{L}≥i_{LIM1}, i_{L}<i_{LIM2}), the discharge current i_{REG}=i_{GS,on} compensates for the current i_{GS,on} output by the control circuit 12 and, consequently, the effective gate current i_{G}=i_{GS,on}−i_{REG} equals to zero amperes. For this special case, the circuit of FIG. 4 may be modified/improved in accordance with the embodiment shown in FIG. 5.

The circuit of FIG. 5 is mostly the same as the circuit of FIG. 4. Therefore, the following discussion concentrates on the difference between the two circuits. As compared to FIG. 4, the current source Q₃ and the corresponding switch S₃ are omitted in the current control circuit 15 of FIG. 5. Instead the output of comparator K₃ is supplied to the input logic 121 of the control circuit 12. The output signal of comparator K₃ is denoted as S_{QA,off} in FIG. 5.

In the second scenario (i.e. when the condition i_{L}≥i_{LIM1} is fulfilled), the current sense voltage V_{CS3} reaches or exceeds the reference voltage V_{REF} (V_{CS3}≥V_{REF}, V_{CS2}<V_{REF}, V_{CS1}<V_{REF}) and, as a consequence, the comparator K₃ outputs a High level (logic level S_{QA,off}=1) indicating the condition i_{L}≥i_{LIM1} being fulfilled. The signal S_{QA,off} is received by the input logic 121, which is configured to switch off the electronic switch S_{A} in response to a the signal S_{QA,off} having a High level, and a switch-on of the electronic switch S_{A} is prevented, by the input logic 121, as long as the signal S_{QA,off} has a High level. The effect of the current sense voltage V_{CS3} reaching the reference voltage V_{REF} is the same as in the previous example of FIG. 4, namely, the effective gate current i_{G} is reduced from i_{GS,on} to zero amperes. However, the example of FIG. 5 has the advantage that there is no need for matched current sources, whereas, in FIG. 5, the current sources Q_{A} and Q₃ have to be designed to generate exactly the same current i_{GS,on} in order to achieve the mentioned compensation (i.e. to achieve that the superposition i_{GS,on}−i_{REG} exactly equals zero).

It can be concluded from FIG. 5 that the current control circuit 15 may also be regarded as part of the control circuit 12 because an increase in the discharge current i_{REG} is equivalent to a decrease of the current output by the control circuit 12. In particular. Increasing the discharge current i_{REG} from zero to i_{GS,on} is equivalent to reducing the output current of the control circuit 12 from i_{GS,on} to zero (while keeping i_{REG} at zero). In both cases the effective gate current i_{G} is zero.

The circuit of FIG. 6 is very similar to the example of FIG. 5. Again, only the differences between these two circuits are discussed below. As compared to FIG. 6, the current source Q₂ and the corresponding switch S₂ are omitted in the current control circuit 15 of FIG. 6. Instead the output of comparator K₂ is supplied to the input logic 121 of the control circuit 12. The output signal of comparator K₂ is denoted as S_{QB,on} in FIG. 6.

In the third scenario (i.e. when the condition i_{L}≥I_{LIM2} is fulfilled), the current sense voltage V_{CS2} reaches or exceeds the reference voltage V_{REF} (V_{CS2}≥V_{REF}, V_{CS3}≥V_{REF}, V_{CS1}<V_{REF}) and, as a consequence, the comparator K₂ outputs a High level (logic level S_{QB,on}=1) indicating the condition i_{L}≥I_{LIM2} being fulfilled. The signal S_{QB,on} is received by the input logic 121, which is configured to switch on the electronic switch S_{B} in response to the signal S_{QB,on} having a High level. At the same time, the electronic switch S_{A} is already off due to the signal S_{QA,off} as discussed above with reference to FIG. 5. The effect of the current sense voltage V_{CS2} reaching the reference voltage V_{REF} is the same as in the previous example of FIG. 5 if i_{GS,off} of current source Q_{B} equals i₂ of current source Q₂. In both examples (FIGS. 5 and 6) the effective gate current i_{G} equals −i₂ (if i₂=i_{GS,off}) in the third scenario.

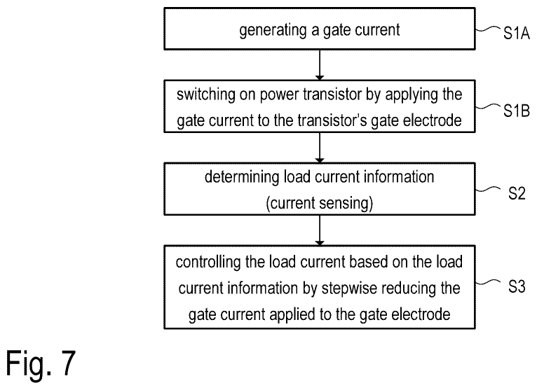

The methods and functions implemented by the embodiments described above are now summarized with reference to the flow chart of FIG. 7. It is emphasized that the following is not an exhaustive listing of functions and method steps but rather an exemplary summary of technical features.

In accordance with one embodiment, the method includes the generation of a gate current (cf. FIG. 7, step S1A) and switching on a power transistor (cf. FIG. 7, step S1B) by applying the gate current i_{G}=i_{G0} to the gate electrode of the power transistor (see, e.g., FIGS. 2, 4, and 5; control circuit 12 outputs the gate current i_{G0}=i_{GS,on} when the input signal V_{IN} indicates a switch-on). The method further includes determining information regarding a load current passing through the power transistor (cf. FIG. 7, step S2; see also, e.g., FIGS. 2, 4, and 5, current sense circuit 13). The mentioned information regarding the load current may be a current sense signal such as the voltage signals V_{CS1}, V_{CS2}, and V_{CS3} discussed above with reference to FIGS. 2 and 4. Furthermore, the method includes controlling—based on the determined information regarding the load current—the load current by reducing the gate current i_{G} applied to the gate electrode of the power transistor (cf. FIG. 7, step S3). The gate current i_{G} is reduced in discrete steps as outlined in the following: When the load current exceeds a first threshold value i_{LIM1} (which is indicated by the determine information regarding the load current), then the gate current i_{G} is reduced by a specific (predetermined) amount, e.g. from i_{G}=i_{G0}=i_{GS,on} to i_{G}=0. When the load current exceeds a further threshold value i_{OC} (third threshold value in the example FIG. 3), then the gate current is reduced by sinking a discharge current from the gate electrode of the power transistor. In this situation, the level of the discharge current corresponds to a third current level (see, e.g., FIG. 3, i_{REF}=i_{OFF,fast}).

In one embodiment, the third current level (i_{REG}=i_{OFF,fast}) is so high that the power transistor is completely switched off. In some embodiments, the third current level is at least sufficiently high to reduce the gate voltage of the power transistor such that the load current falls below the third threshold value.

In some embodiments the reduction of the gate current is accomplished in three steps. For example, when the load current exceeds a second threshold value i_{LIM2} (see, e.g. FIG. 3), then the gate current is reduced by setting the discharge current, which is sunk from the gate electrode, to a second current level. This second current level may be so high that the gate current becomes negative and the gate-source capacitance of the power transistor is actively discharged. The mentioned third threshold value i_{OC} is greater than the second threshold value i_{LIM2}, and the second threshold value i_{LIM2}, is greater than the first threshold value i_{LM1} (see, e.g., FIG. 3).

In the first step the reduction of the gate current may be accomplished in two ways. Accordingly, when the load current exceeds the first threshold value i_{LM1}, the gate current may be reduced by setting the discharge current, which is sunk from the gate electrode, to a first current level. If, this first current level is the same as the normal gate current uses to switch on the power transistor (i_{REG}=i_{GS,on}), the gate current is reduced to substantially zero. Alternatively, the control circuit that outputs the gate current to the gate electrode of the power transistor may reduce the gate current (e.g. to zero) without requiring a discharge current in this situation (see, e.g., FIG. 5, signal S_{QA,off} causes the deactivation of the current source that provides the gate current i_{GA,on}). However, the discharge current is necessary when the gate electrode is to be actively discharged to reduce the load current of the power transistor.

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. An integrated circuit comprising:
a power transistor connected between a supply terminal and an output terminal;
a control circuit coupled to a gate electrode of the power transistor and configured to apply a gate current to the gate electrode to turn the power transistor on or off;
a current sensing circuit configured to provide information regarding a load current passing through the power transistor;
a current control circuit coupled to the gate electrode and configured to generate a discharge current for discharging the gate based on the information regarding the load current,
wherein a level of the discharge current corresponds to a first current level in response to the load current exceeding a first threshold value; and
wherein the level of the discharge current corresponds to a third current level in response to the load current exceeding a third threshold value.

2. The integrated circuit of claim 1,
wherein the level of the discharge current corresponds to a second current level in response to the load current exceeding a second threshold value,
wherein the third current level is greater than the second current level and the second current level is greater than the first current level.

3. The circuit according to claim 2,
wherein the third threshold value is greater than the second threshold value and the second threshold value is greater than the first threshold value.

4. The integrated circuit of claim 1,
wherein the third current level is so high that the transistor is completely switched off.

5. The integrated circuit of claim 1,
wherein the third current level is sufficiently high to reduce the gate voltage such that the load current falls below the third threshold value.

6. The circuit according to claim 1,
wherein the current control circuit is configured to generate the discharge current for discharging the gate, while the control circuit drives the power transistor to turn it on or keep it on.

7. The circuit according to claim 1,
wherein the current sense circuit comprises a sense transistor coupled to the power transistor, and
wherein the load current information is based on and amount of current passing through the sense transistor or is based on a voltage drop across at least one sense resistor coupled to the sense transistor.

8. The circuit according to claim 1,
wherein the current control circuit comprises a plurality of comparators configured to compare a sensor signal representing the load current with at least the first threshold value and the third threshold value.

9. The circuit of claim 8,
wherein the comparators have a hysteresis.

10. The circuit according to claim 8,
wherein the discharge current generated by the current control circuit depends on output signals of the comparators.

11. An integrated circuit comprising:
a power transistor connected between a supply terminal and an output terminal;
a control circuit coupled to a gate electrode of the power transistor and configured to apply a gate current to the gate electrode to turn the power transistor on or off;
a current sensing circuit configured to provide information regarding a load current passing through the power transistor;
a current control circuit coupled to the gate electrode and configured to generate a discharge current for discharging the gate based on the information regarding the load current and to cause the control circuit to reduce the gate current while the power transistor is switched on,
wherein the gate current output by the control circuit is reduced in response to the load current exceeding a first threshold value (i_{LIM1}); and
wherein the level of the discharge current is set to a third current level in response to the load current exceeding a third threshold value.

12. The integrated circuit of claim 11,
wherein the gate current output by the control circuit is reduced to zero in response to the load current exceeding the first threshold value.

13. The integrated circuit of claim 11,
wherein the level of the discharge current is set to a second current level in response to the load current exceeding a second threshold value,
wherein the third current level is greater than the second current level and the second current level is greater than the first current level.

14. A method comprising:
generating a gate current;
switching on a power transistor by applying the gate current to a gate electrode of the power transistor;
determining information regarding a load current passing through the power transistor;
controlling, based on the information regarding the load current, the load current by reducing the gate current applied to the gate electrode of the power transistor;
wherein—in response to the load current exceeding a first threshold value—the gate current is reduced by a specific amount; and
wherein—in response to the load current exceeding a third threshold value—the gate current is further reduced by sinking a discharge current, which has a third current level, from the gate electrode of the power transistor.

15. The method of claims 14,
wherein the third current level is so high that the transistor is completely switched off.

16. The method of claim 14,
wherein the third current level is sufficiently high to reduce the gate voltage such that the load current falls below the third threshold value.

17. The method of claim 14,
wherein—in response to the load current exceeding a second threshold value—the gate current is reduced by setting the discharge current, which is sunk from the gate electrode, to a second current level.

18. The method of claim 17,
wherein the third threshold value is greater than the second threshold value and the second threshold value is greater than the first threshold value.

19. The method of claim 14,
wherein—in response to the load current exceeding the first threshold value—the gate current is reduced by setting the discharge current, which is sunk from the gate electrode, to a first current level.

20. The method of claim 14,
wherein—in response to the load current exceeding the first threshold value—the gate current is reduced to approximately zero.
